(19) United States
(12) Patent Application Publication
(10) Pub. No.: US 2026/0164749 A1
(43) Pub. Date: Jun. 11, 2026

(54) SEMICONDUCTOR DEVICE

(71) Applicant: TOYODA GOSEI CO., LTD., Kiyosu-shi (JP)

(72) Inventors: Takaki NIWA, Aichi (JP); Kazuya HASEGAWA, Aichi (JP); Tsutomu INA, Aichi (JP); Tetsuya MATSUTANI, Aichi (JP)

(21) Appl. No.: 19/180,631

(22) Filed: Apr. 16, 2025

(30) Foreign Application Priority Data
Apr. 25, 2024 (JP) 2024-071057

(51) Int. Cl. H10D 64/00; H10D 30/66

(52) U.S. Cl. CPC H10D 64/117; H10D 30/668

(57) ABSTRACT

A semiconductor device includes: a substrate containing a first conductivity type semiconductor; a first semiconductor layer being over the substrate and containing a first conductivity type nitride semiconductor; a second semiconductor layer being over the first semiconductor layer and containing a second conductivity type nitride semiconductor; a third semiconductor layer being over the second semiconductor layer and having a first conductivity type; a gate trench penetrating the third and second semiconductor layers to reach the first semiconductor layer; a gate insulating film along a bottom surface and a side surface of the gate trench; a gate electrode along the bottom surface and the side surface of the gate trench via the gate insulating film; a dummy gate trench; a dummy gate insulating film along a bottom surface and a side surface of the dummy gate trench; a dummy gate electrode; and a buried layer as defined herein.

### CROSS-REFERENCE TO RELATED APPLICATION

This application is based on and claims priority under 35 USC 119 from Japanese Patent Application No. 2024-071057 filed on April 25, 2024.

### TECHNICAL FIELD

The present invention relates to a semiconductor device.

### BACKGROUND ART

In a semiconductor device having a gate trench structure, there is known a structure in which a dummy gate trench is formed near a gate trench, a dummy gate insulating film is formed on a bottom surface and a side surface of the dummy gate trench, and a dummy gate electrode buried in the dummy gate trench is formed via the dummy gate insulating film (see Patent Literature 1). By providing such a dummy gate trench structure, breakdown of the gate trench when a high voltage is applied can be prevented.

Patent Literature 1: JP2014-179373A

### SUMMARY OF INVENTION

However, the inventors have found, through investigation that, in the case of a nitride semiconductor, particularly GaN, when a metal is buried inside the dummy gate trench as in Patent Literature 1, a stress is generated in the dummy gate trench when a temperature changes, and various problems occur. For example, it has been found that a crack or a defect is generated in a semiconductor layer, or a decrease in device performance such as a device property fluctuation, current leakage, or a decrease in reliability occurs due to polarization charges caused by the stress.

The present invention has been made in view of such a background, and an object thereof is to provide a semiconductor device in which a stress generated in a dummy gate trench is prevented.

An aspect of the present invention relates to a semiconductor device including:

a substrate made of a first conductivity type semiconductor;

a first semiconductor layer provided on the substrate and made of a first conductivity type nitride semiconductor;

a second semiconductor layer located on the first semiconductor layer and made of a second conductivity type nitride semiconductor;

a third semiconductor layer located on the second semiconductor layer and having a first conductivity type;

a gate trench penetrating the third semiconductor layer and the second semiconductor layer to reach the first semiconductor layer;

a gate insulating film provided in a film shape along a bottom surface and a side surface of the gate trench;

a gate electrode provided in a film shape along the bottom surface and the side surface of the gate trench via the gate insulating film;

a dummy gate trench provided apart from the gate trench, penetrating the third semiconductor layer and the second semiconductor layer to reach the first semiconductor layer, and deeper than the gate trench;

a dummy gate insulating film provided in a film shape along a bottom surface and a side surface of the dummy gate trench;

a dummy gate electrode provided in a film shape along the bottom surface and the side surface of the dummy gate trench via the dummy gate insulating film; and

a buried layer made of a material having a smaller thermal expansion coefficient than the dummy gate electrode, provided on the dummy gate electrode, and burying an inside of the dummy gate trench.

Another aspect of the present invention relates to a semiconductor device including:

a substrate made of a first conductivity type semiconductor;

a first semiconductor layer provided on the substrate and made of a first conductivity type nitride semiconductor;

a second semiconductor layer located on the first semiconductor layer and made of a second conductivity type nitride semiconductor;

a third semiconductor layer located on the second semiconductor layer and having a first conductivity type;

a gate trench penetrating the third semiconductor layer and the second semiconductor layer to reach the first semiconductor layer;

a gate insulating film provided in a film shape along a bottom surface and a side surface of the gate trench;

a gate electrode provided in a film shape along the bottom surface and the side surface of the gate trench via the gate insulating film;

a dummy gate trench provided apart from the gate trench, penetrating the third semiconductor layer and the second semiconductor layer to reach the first semiconductor layer;

a dummy gate insulating film provided in a film shape along a bottom surface and a side surface of the dummy gate trench; and

a dummy gate electrode provided in a film shape along the bottom surface and the side surface of the dummy gate trench via the dummy gate insulating film, in which

a void is formed inside the dummy gate trench near the bottom surface without the dummy gate trench being buried.

In the above aspects, the material having a smaller thermal expansion coefficient than the dummy gate electrode is buried inside the dummy gate trench via the dummy gate electrode. Alternatively, the void is formed without the inside of the dummy gate trench being buried. Therefore, it is possible to reduce the stress generated in the dummy gate trench due to a difference in thermal expansion coefficient when a temperature changes. As a result, cracks and defects in the semiconductor layer can be prevented. In addition, generation of piezoelectric charges caused by the stress can be prevented, and a decrease in device performance can be prevented.

As described above, in the above aspects, it is possible to provide a semiconductor device in which a stress generated in a dummy gate trench is prevented.

### BRIEF DESCRIPTION OF DRAWINGS

FIG. 1 is a cross-sectional view showing a configuration of a semiconductor device according to a first embodiment, which is a cross-sectional view perpendicular to a substrate main surface.

FIG. 2 is a diagram showing a plane pattern of trenches.

FIG. 3 is a diagram showing a step of producing the semiconductor device according to the first embodiment.

FIG. 4 is a diagram showing a step of producing the semiconductor device according to the first embodiment.

FIG. 5 is a diagram showing a step of producing the semiconductor device according to the first embodiment.

FIG. 6 is a diagram showing a step of producing the semiconductor device according to the first embodiment.

FIG. 7 is a diagram showing a step of producing the semiconductor device according to the first embodiment.

FIG. 8 is a diagram showing a step of producing the semiconductor device according to the first embodiment.

FIG. 9 is a diagram showing a step of producing the semiconductor device according to the first embodiment.

FIG. 10 is a diagram showing a step of producing the semiconductor device according to the first embodiment.

FIG. 11 is a diagram showing a step of producing the semiconductor device according to the first embodiment.

FIG. 12 is a cross-sectional view showing a configuration of a semiconductor device according to a second embodiment, which is a cross-sectional view perpendicular to a substrate main surface.

FIG. 13 is a cross-sectional view showing a configuration of a semiconductor device according to a third embodiment, which is a cross-sectional view perpendicular to a substrate main surface.

### DESCRIPTION OF EMBODIMENTS

A first semiconductor device includes: a substrate made of a first conductivity type semiconductor; a first semiconductor layer provided on the substrate and made of a first conductivity type nitride semiconductor; a second semiconductor layer located on the first semiconductor layer and made of a second conductivity type nitride semiconductor; a third semiconductor layer located on the second semiconductor layer and having a first conductivity type; a gate trench penetrating the third semiconductor layer and the second semiconductor layer to reach the first semiconductor layer; a gate insulating film provided in a film shape along a bottom surface and a side surface of the gate trench; a gate electrode provided in a film shape along the bottom surface and the side surface of the gate trench via the gate insulating film; a dummy gate trench provided apart from the gate trench, penetrating the third semiconductor layer and the second semiconductor layer to reach the first semiconductor layer, and deeper than the gate trench; a dummy gate insulating film provided in a film shape along a bottom surface and a side surface of the dummy gate trench; a dummy gate electrode provided in a film shape along the bottom surface and the side surface of the dummy gate trench via the dummy gate insulating film; and a buried layer made of a material having a smaller thermal expansion coefficient than the dummy gate electrode, provided on the dummy gate electrode, and burying an inside of the dummy gate trench.

In the first semiconductor device, the buried layer may have a void. A stress generated in the dummy gate trench can be further reduced.

In the first semiconductor device, the buried layer may be formed to a position higher than the second semiconductor layer. A stress generated in the dummy gate trench can be further reduced.

In the first semiconductor device, the dummy gate trench may have a width of 0.5 μm to 3 μm.

A second semiconductor device includes: a substrate made of a first conductivity type semiconductor; a first semiconductor layer provided on the substrate and made of a first conductivity type nitride semiconductor; a second semiconductor layer located on the first semiconductor layer and made of a second conductivity type nitride semiconductor; a third semiconductor layer located on the second semiconductor layer and having a first conductivity type; a gate trench penetrating the third semiconductor layer and the second semiconductor layer to reach the first semiconductor layer; a gate insulating film provided in a film shape along a bottom surface and a side surface of the gate trench; a gate electrode provided in a film shape along the bottom surface and the side surface of the gate trench via the gate insulating film; a dummy gate trench provided apart from the gate trench, penetrating the third semiconductor layer and the second semiconductor layer to reach the first semiconductor layer; a dummy gate insulating film provided in a film shape along a bottom surface and a side surface of the dummy gate trench; and a dummy gate electrode provided in a film shape along the bottom surface and the side surface of the dummy gate trench via the dummy gate insulating film, in which a void is formed inside the dummy gate trench near the bottom surface without the dummy gate trench being buried.

In the second semiconductor device, the void may be formed to a position higher than the second semiconductor layer. A stress generated in the dummy gate trench can be further reduced.

In the second semiconductor device, the dummy gate trench may have a width of 0.5 μm to 1.5 μm.

The first or second semiconductor device may further include: a recess provided apart from the gate trench and penetrating the third semiconductor layer to reach the second semiconductor layer, in which the dummy gate trench may be formed inside the recess in a plan view.

### First Embodiment

### 1. Configuration of Semiconductor Device

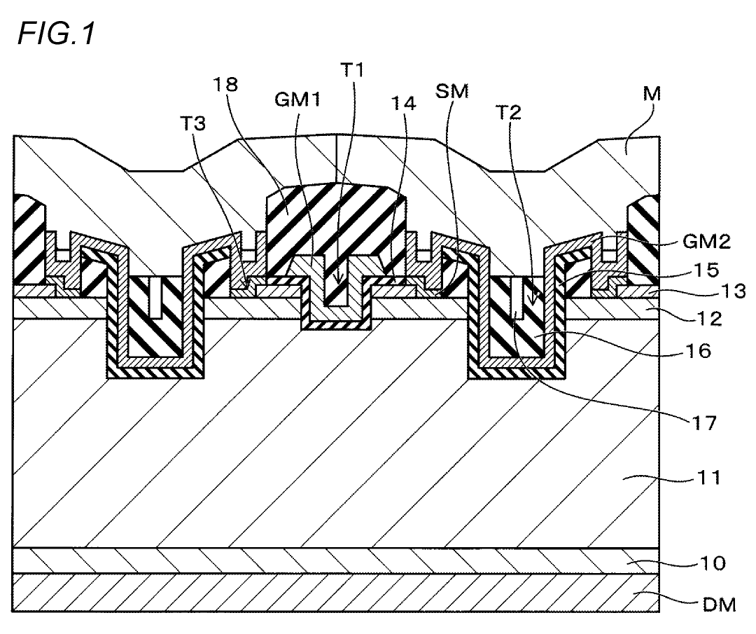

FIG. 1 is a cross-sectional view showing a configuration of a semiconductor device according to a first embodiment, which is a cross-sectional view perpendicular to a substrate main surface. The semiconductor device according to the first embodiment is a MISFET having a gate trench structure and a dummy gate trench structure. By providing the dummy gate trench structure near the gate trench structure, breakdown of the gate trench structure in the case where a high drain voltage is applied can be prevented. The semiconductor device according to the first embodiment has a structure in which regular hexagonal unit cells are arranged in a honeycomb shape in a plan view, and has a structure in which the unit cells are connected in parallel.

As shown in FIG. 1, the semiconductor device according to the first embodiment includes a substrate 10, a drift layer 11, a p-type layer 12, an n-type layer 13, a gate trench T1, a dummy gate trench T2, a recess T3, a gate insulating film 14, a dummy gate insulating film 15, a gate electrode GM1, a dummy gate electrode GM2, a source electrode SM, a drain electrode DM, a wiring electrode M, a buried layer 16, a void 17, and an interlayer insulating film 18. The gate trench T1, the gate insulating film 14, and the gate electrode GM1 constitute a gate trench structure. The dummy gate trench T2, the dummy gate insulating film 15, and the dummy gate electrode GM2 constitute a dummy gate trench structure. Both the gate trench structure and the dummy gate trench structure are a MIS structure.

The substrate 10 is made of Si-doped n⁺-GaN having a c plane as a main surface. A Si concentration in the substrate 10 is 1 × 10¹⁸/cm³ or more. A material of the substrate 10 may be a material other than GaN, and any material can be used as long as the material can grow a nitride semiconductor and has conductivity. For example, Si, SiC, or ZnO can be used. However, it is preferable to use a nitride semiconductor, particularly GaN as in the first embodiment.

The drift layer 11 is provided on the substrate 10. The drift layer 11 is made of Si-doped n·-GaN. A thickness of the drift layer 11 is 8 μm to 15 μm in the case of a breakdown voltage device of 600 V or more, and is 0.5 μm to 3 μm in the case of a low breakdown voltage device of 100 V or less. In addition, a Si concentration in the drift layer 11 is 1 × 10¹⁵/cm³ to 5 × 10¹⁶/cm³.

The p-type layer 12 is provided on the drift layer 11. The p-type layer 12 is made of Mg-doped p-GaN. A thickness of the p-type layer 12 is 0.3 μm to 1.5 μm. A Mg concentration in the p-type layer 12 is 1 × 10¹⁸/cm³ to 2 × 10¹⁹/cm³. It is preferably 1 × 10¹⁸/cm³ to 6 × 10¹⁸/cm³.

The n-type layer 13 is provided on the p-type layer 12. The n-type layer 13 is formed of Si-doped n -GaN. A thickness of the n-type layer 13 is 0.1 μm to 0.5 μm. In addition, a Si concentration in the n-type layer 13 is 1 × 10¹⁸/cm³ to 5 × 10¹⁹/cm³.

The interlayer insulating film 18 is provided on the gate insulating film 14, the gate electrode GM1, the n-type layer 13, and the p-type layer 12 at a bottom surface of the recess T3. The interlayer insulating film 18 is made of, for example, SiO₂.

The gate trench T1 and the recess T3 are each provided in a predetermined region on a surface of the n-type layer 13. In addition, the dummy gate trench T2 is provided in a predetermined region on the interlayer insulating film 18.

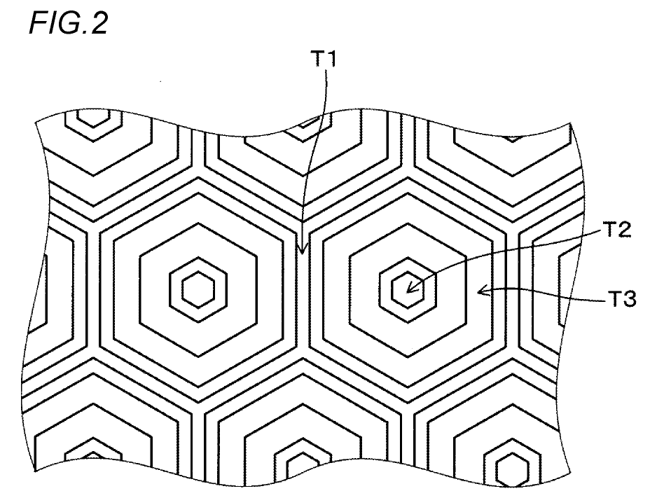

FIG. 2 is a diagram showing plane patterns of the gate trench T1, the dummy gate trench T2, and the recess T3. As shown in FIG. 2, the plane pattern of the recess T3 is a pattern in which regular hexagons are arranged in a honeycomb shape. The plane pattern of the gate trench T1 is a honeycomb pattern provided between the regular hexagons of the recess T3. The plane pattern of the dummy gate trench T2 is a regular hexagonal pattern that is included inside the regular hexagon of the recess T3 and that is concentric with the regular hexagon of the recess T3. In the first embodiment, a device area per unit cell increases since the dummy gate trench T2 is provided, and the increase in device area per unit cell can be prevented by forming a pattern in which the dummy gate trench T2 is inside the recess T3 in a plan view. Sides of the regular hexagon of the recess T3 and the dummy gate trench T2 preferably coincide with an m plane of GaN.

Note that, in the first embodiment, the pattern of the unit cell is not limited to a regular hexagon, and the plane patterns of the gate trench T1, the dummy gate trench T2, and the recess T3 are not limited to the above. The pattern may be a stripe pattern, a square lattice pattern, or the like.

The gate trench T1 is a recess having a depth reaching the drift layer 11 through the n-type layer 13 and the p-type layer 12. The drift layer 11 is exposed at a bottom surface of the gate trench T1. On a side surface of the gate trench T1, the drift layer 11, the p-type layer 12, and the n-type layer 13 are exposed in order from a bottom surface side. The p-type layer 12 exposed at the side surface of the gate trench T1 operates as a channel.

The dummy gate trench T2 is a recess having a depth reaching the drift layer 11 through the interlayer insulating film 18, the n-type layer 13, and the p-type layer 12. The depth of the dummy gate trench T2 is deeper than that of the gate trench T1. That is, a height from a front surface of the substrate 10 to a bottom surface of the dummy gate trench T2 is smaller than a height from the front surface of the substrate 10 to the bottom surface of the gate trench T1. By making the dummy gate trench T2 deeper than the gate trench T1 in this manner, an electric field at a corner portion of the gate trench T1 can be relaxed. For example, the dummy gate trench T2 is preferably deeper than the gate trench T1 by 0.5 μm to 2 μm.

A width of the dummy gate trench T2 is preferably 0.5 μm to 3 μm. By setting the width of the dummy gate trench T2 to such a range, the void 17 can be easily formed in the buried layer 16. The thickness is preferably 1 μm to 3 μm.

The recess T3 is a recess having a depth reaching the p-type layer 12 through the n-type layer 13. The recess T3 is provided to bring the source electrode SM into contact with the p-type layer 12.

The gate insulating film 14 is continuously provided in a film shape along the bottom surface, the side surface, and an upper surface of the gate trench T1 (on the n-type layer 13 near the gate trench T1). A material of the gate insulating film 14 is SiO₂, SiN, SiON, Al₂O₃, or the like, and a thickness thereof is, for example, 50 nm.

The gate electrode GM1 is continuously provided in a film shape along the bottom surface, the side surface, and the upper surface of the gate trench T1 via the gate insulating film 14. A material of the gate electrode GM1 is TiN or the like, and a thickness thereof is, for example, 600 nm. The interlayer insulating film 18 is provided on the gate electrode GM1.

The source electrode SM is continuously provided on the p-type layer 12 exposed at the bottom surface of the recess T3 and on the n-type layer 13. A material of the source electrode SM is, for example, Ti/Al, Ti/Al/Ti, V/Al/Ti, or Pd/Al/Ti. Note that, the source electrode SM may include a first layer provided on the p-type layer 12 and a second layer provided continuously on the n-type layer 13 and on the first layer. Materials of the first layer and the second layer can be changed to optimize contact with the p-type layer 12 and contact with the n-type layer 13, respectively. In this case, Pd or Ni may be used as the material of the first layer, and Ti/Al may be used as the material of the second layer.

The drain electrode DM is provided on an entire back surface of the substrate 10. A material of the drain electrode DM is, for example, Ti/Al, Ti/Al/Ti, V/Al/Ti, or Pd/Al/Ti.

The dummy gate insulating film 15 is continuously provided in a film shape along the bottom surface, a side surface, and an upper surface of the dummy gate trench T2 (on the interlayer insulating film 18 near the dummy gate trench T2). In the first embodiment, since the electric field applied to the corner portion of the gate trench T1 is relaxed by providing the dummy gate trench structure near the gate trench structure, a strong electric field is applied to a corner portion of the dummy gate trench T2. Therefore, the dummy gate trench structure has a MIS structure having a high breakdown voltage.

In order to form a MIS structure having a high breakdown voltage, the dummy gate insulating film 15 may be thicker than the gate insulating film 14. For example, a thickness of the dummy gate insulating film 15 is 2 times to 10 times the thickness of the gate insulating film 14. Alternatively, a material having a critical electric field higher than that of the gate insulating film 14 may be used as a material of the dummy gate insulating film 15. For example, Al₂O₃, SiO₂/Al₂O₃, or the like is preferably used as the material of the dummy gate insulating film 15. In addition, SiN or Al₂O₃ having a dielectric constant higher than that of SiO₂ is suitably used since the electric field in the insulating film decreases, which makes it difficult to break the insulating film.

Note that, in the first embodiment, the n-type layer 13 is removed and the p-type layer 12 is exposed in a region from a region where the source electrode SM is provided to the dummy gate trench T2, but the n-type layer 13 may remain.

The dummy gate insulating film 15 is located on the p-type layer 12 via the interlayer insulating film 18 near the dummy gate trench T2, or may be located directly on the p-type layer 12 without forming the interlayer insulating film 18. However, by providing the interlayer insulating film 18, the void 17 to be described later can be easily formed.

The dummy gate electrode GM2 is continuously provided in a film shape along the bottom surface, the side surface, and the upper surface of the dummy gate trench T2 via the dummy gate insulating film 15, and is further provided continuously on the source electrode SM at the bottom surface of the recess T3. By connecting the dummy gate electrode GM2 to the source electrode SM, a potential of the dummy gate electrode GM2 is stabilized. A material of the dummy gate electrode GM2 is a metal such as TiN, and may be the same as the material of the gate electrode GM1. The dummy gate electrode GM2 is formed such that the dummy gate trench T2 is not buried. For example, it is formed to have a thickness of 100 nm to 600 nm.

The buried layer 16 is provided on the dummy gate electrode GM2 in the dummy gate trench T2, and is provided such that the inside of the dummy gate trench T2 is not buried via the dummy gate electrode GM2. A material of the buried layer 16 is a material having a thermal expansion coefficient smaller than that of the dummy gate electrode GM2, and is, for example, a non-metal such as poly-Si or SiO₂. When the buried layer 16 is made of n-type poly-Si or the like, electrical resistance to the dummy gate electrode GM2 is lowered. However, in a heating step, when Si reacts with Ti, a silicide is formed and the volume decreases, so that a stress is generated. Therefore, in the case of using poly-Si as the material of the buried layer 16, the void 17 is preferably present. Accordingly, application of a stress can be prevented.

A difference in thermal expansion coefficient between the buried layer 16 and the semiconductor layer is smaller than a difference in thermal expansion coefficient between the dummy gate electrode GM2 and the semiconductor layer. Therefore, a strain due to the difference in thermal expansion coefficient can be reduced in the case where the inside of the dummy gate trench T2 is buried by the buried layer 16 than in the case where the inside of the dummy gate trench T2 is buried by the dummy gate electrode GM2. In the case of GaN, when a stress is generated, unintended piezoelectric charges are generated, and a property fluctuation and property deterioration occur. In the structure in the first embodiment, since the difference in the thermal expansion coefficient is small, it is possible to reduce the stress generated in the dummy gate trench T2 due to a temperature change during the heating step in forming the semiconductor device or during a device operation, and it is possible to prevent the generation of the piezoelectric charges.

The buried layer 16 is provided with the void 17, that is, a space in which air is confined. As to be described later, the void 17 is formed such that the dummy gate trench T2 is not sufficiently buried by the buried layer 16 during formation, and is located substantially at a center of the dummy gate trench T2 in a plan view. By providing the void 17, the strain due to the difference in thermal expansion coefficient can be absorbed by the void 17. Therefore, the stress generated in the dummy gate trench T2 can be further reduced.

The void 17 may be formed by being surrounded by the buried layer 16 and the wiring electrode M as shown in FIG. 1, or may be formed by being surrounded only by the buried layer 16.

The buried layer 16 does not need to bury the entire inside of the dummy gate trench T2, and sufficiently buries the dummy gate trench T2 to such an extent that the stress generated in the dummy gate trench T2 can be reduced than the case where the entire inside of the dummy gate trench T2 is buried by the dummy gate electrode GM2. However, a height of the buried layer 16 (a height of the bottom surface of the dummy gate trench T2 from a surface of the dummy gate electrode GM2) is a height, for example, equal to or higher than an upper surface of the p-type layer 12. Accordingly, the stress applied from the dummy gate trench T2 to the p-type layer 12 and the drift layer 11 made of GaN can be reduced.

The height of the buried layer 16 may be a height equal to or higher than an upper surface of the n-type layer 13. The stress generated in the dummy gate trench T2 can be further reduced. This is because the recess T3 is formed so as not to be in contact with the n-type layer 13 near the dummy gate trench T2, but in the case where the n-type layer 13 is close to the dummy gate trench T2, the stress applied from the dummy gate trench T2 to the n-type layer 13 made of GaN can be further relaxed.

The wiring electrode M is provided on the interlayer insulating film 18 and on the dummy gate electrode GM2. The source electrodes SM of the unit cells are connected in parallel by the wiring electrodes M. The wiring electrode M is provided so as not to bury the void 17 in the buried layer 16.

As described above, in the semiconductor device according to the first embodiment, the inside of the dummy gate trench T2 is buried by the buried layer 16 via the dummy gate insulating film 15 and the dummy gate electrode GM2. Therefore, the difference in thermal expansion coefficient between the semiconductor layer (the drift layer 11, the p-type layer 12, and the n-type layer 13) is smaller than the case where the inside of the dummy gate trench T2 is buried by the dummy gate electrode GM2 via the dummy gate insulating film 15. As a result, the strain due to the difference in thermal expansion coefficient can be reduced, and the stress generated in the dummy gate trench T2 can be prevented. In addition, since the strain due to the stress can be absorbed by the void 17, the stress can be further prevented.

As a result of being able to prevent the stress, cracks and defects in the semiconductor layer can be prevented. In addition, the generation of the piezoelectric charges peculiar to GaN due to the stress can be prevented. As a result of being able to prevent the generation of the piezoelectric charges, it is possible to prevent a decrease in device performance such as an unintended property fluctuation, current leakage, or decrease in reliability. For example, a fluctuation of a threshold voltage can be prevented.

### 2. Method for Producing Semiconductor Device

Next, a method for producing a semiconductor device according to the first embodiment will be described with reference to the drawings.

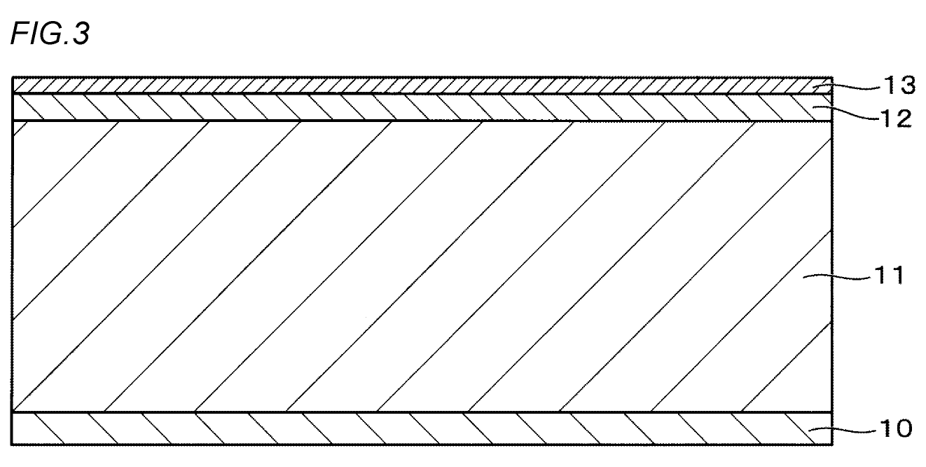

First, the drift layer 11, the p-type layer 12, and the n-type layer 13 are stacked on the substrate 10 in order from the substrate 10 side (see FIG. 3). The method of forming the drift layer 11, the p-type layer 12, and the n-type layer 13 is, for example, a MOCVD method.

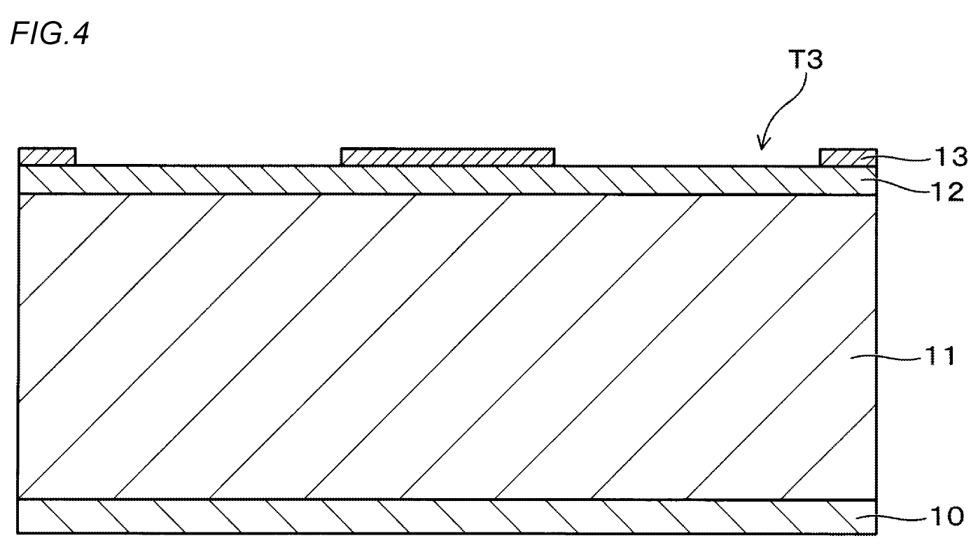

Next, a predetermined region on the n-type layer 13 is dry-etched until the p-type layer 12 is exposed to form the recess T3 (see FIG. 4).

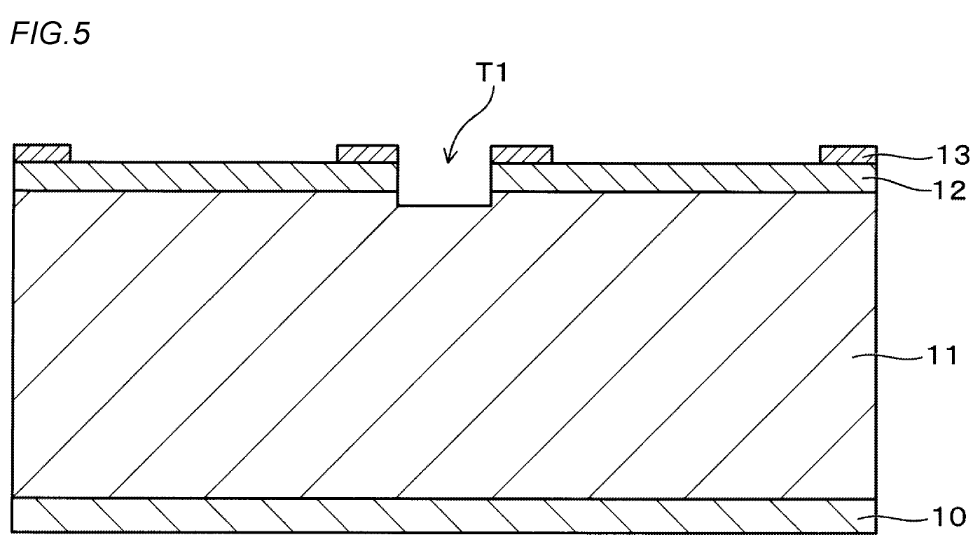

Next, a predetermined region on the n-type layer 13 is dry-etched until the drift layer 11 is exposed to form the gate trench T1 (see FIG. 5).

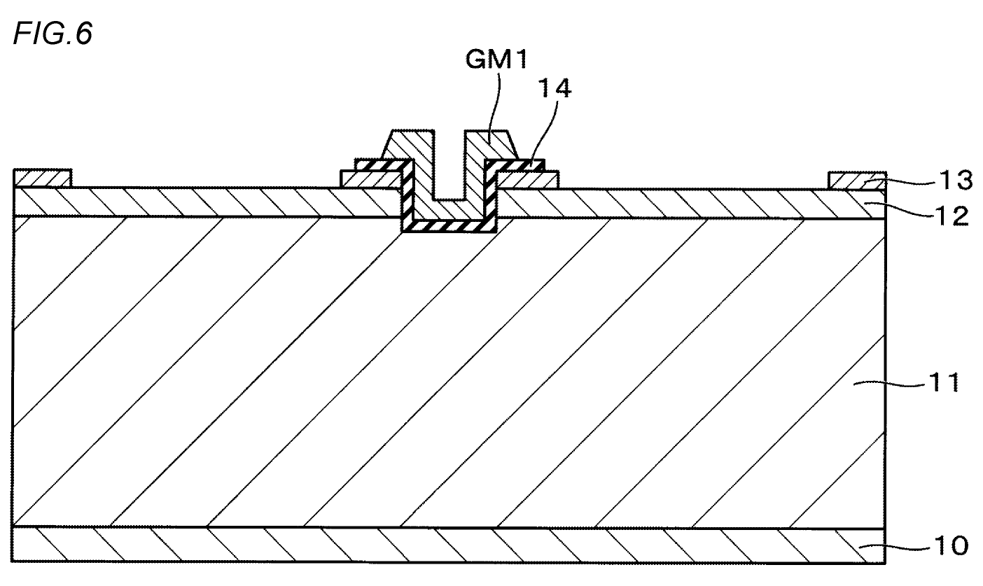

Next, the gate insulating film 14 is formed on an entire upper surface of the device. The method of forming the gate insulating film 14 is an ALD method, a CVD method, or the like. Thereafter, the gate electrode GM1 is formed on the gate insulating film 14. The method of forming the gate electrode GM1 is sputtering, vapor deposition, or the like. Next, the gate electrode GM1 is patterned to leave the gate electrode GM1 on the bottom surface, the side surface, and the upper surface of the gate trench T1, and other regions are removed to expose the gate insulating film 14. Next, the gate insulating film 14 is patterned to leave the gate insulating film 14 on the bottom surface, the side surface, and the upper surface of the gate trench T1, and other regions are removed. With the above, the gate insulating film 14 and the gate electrode GM1 are formed (see FIG. 6).

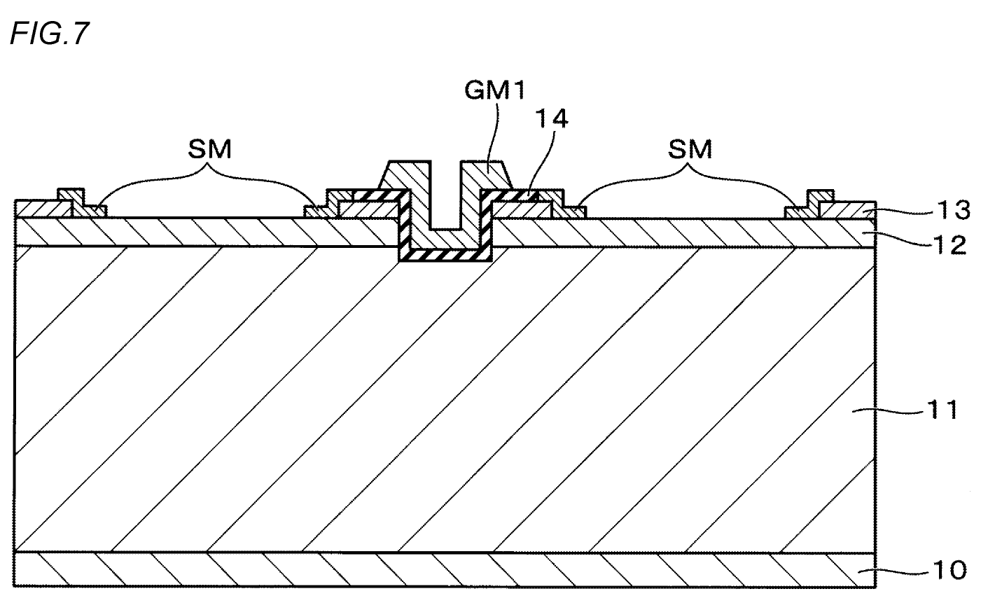

Next, the source electrode SM is continuously formed over a region near the side surface, the side surface, and the surface of the n-type layer 13 at the bottom surface of the recess T3 (see FIG. 7). The method of forming the source electrode SM is vapor deposition or the like.

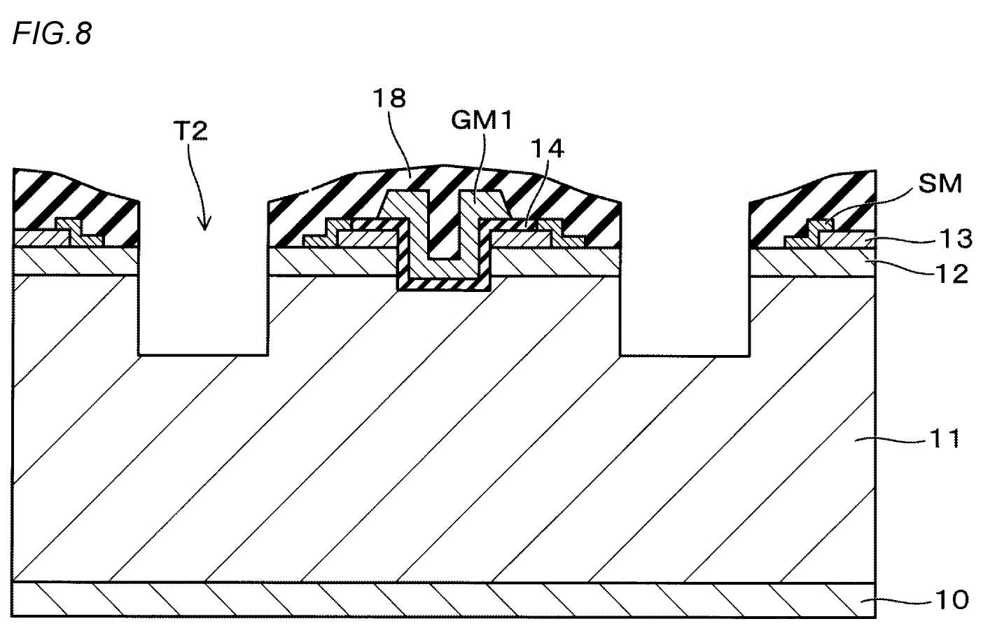

Next, the interlayer insulating film 18 is formed on the entire upper surface of the device, and a predetermined region on the interlayer insulating film 18 is dry-etched until the drift layer 11 is exposed to form the dummy gate trench T2 (see FIG. 8).

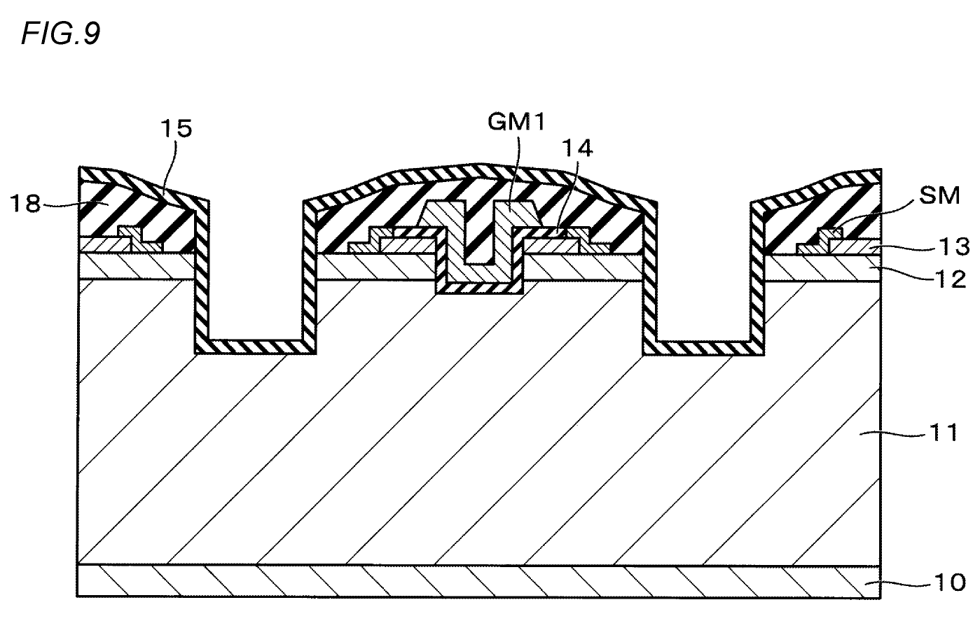

Next, the dummy gate insulating film 15 is formed on the entire upper surface of the device (see FIG. 9). The method of forming the dummy gate insulating film 15 is the same as that of the gate insulating film 14.

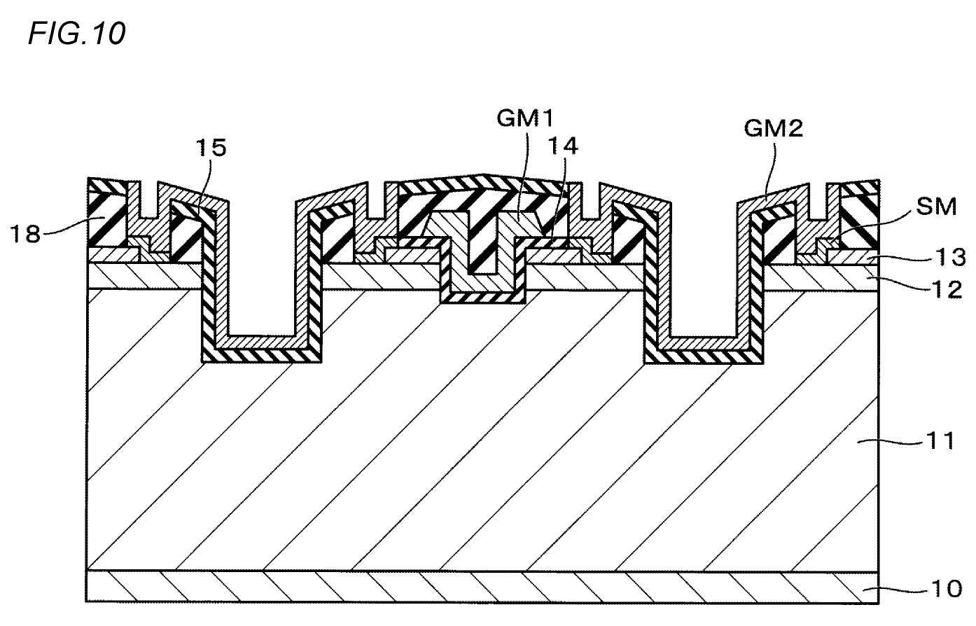

Next, a region on the dummy gate insulating film 15 corresponding to an upper portion of the source electrode SM is dry-etched until the source electrode SM is exposed to form a through hole. Then, the dummy gate electrode GM2 is continuously formed in a film shape on the bottom surface, the side surface, and the upper surface of the dummy gate trench T2, and on the source electrode SM at a bottom surface of the through hole (see FIG. 10).

Next, the buried layer 16 is formed on the entire upper surface of the device by a CVD method or the like. Here, the buried layer 16 is formed to bury the dummy gate trench T2. Further, the void 17 is formed in the buried layer 16 inside the dummy gate trench T2.

In order to form the void 17, the width of the dummy gate trench T2 is preferably reduced. For example, the width is preferably 0.5 μm to 3 μm. With such a width, the insulating film grows to protrude into the dummy gate trench T2 from an upper corner portion of the dummy gate trench T2, a raw material gas is less likely to enter the inside of the dummy gate trench T2, and the void 17 is formed.

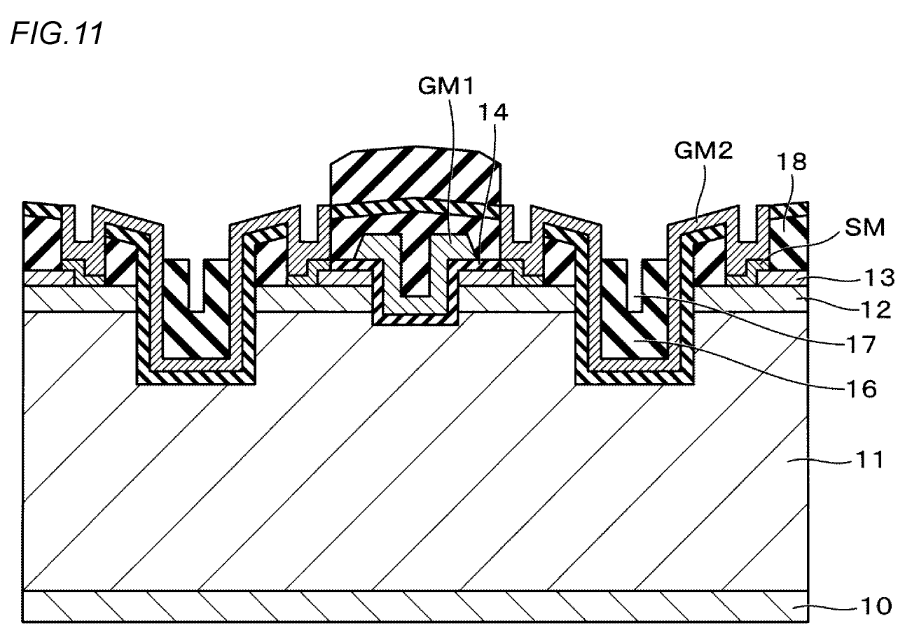

Next, portions of the buried layer 16 other than the portions inside the dummy gate trench T2 are removed by dry etching. With the above, the buried layer 16 is formed inside the dummy gate trench T2 (see FIG. 11).

Next, the wiring electrode M having a predetermined pattern is formed on the gate electrode GM1 and the interlayer insulating film 18. With the above, the semiconductor device according to the first embodiment shown in FIG. 1 is produced.

### Second Embodiment

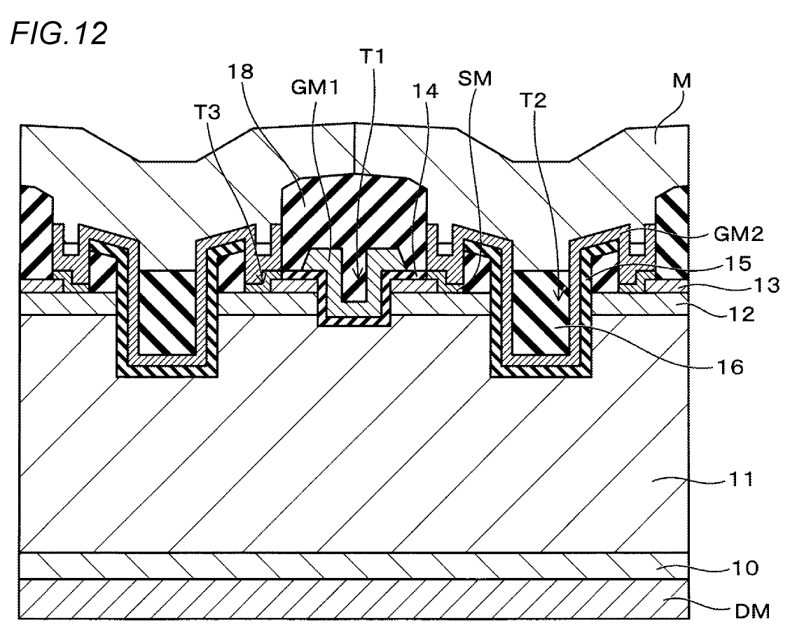

FIG. 12 is a cross-sectional view showing a configuration of a semiconductor device according to a second embodiment, which is a cross-sectional view perpendicular to a substrate main surface. As shown in FIG. 12, the semiconductor device according to the second embodiment has a structure in which the void 17 is eliminated and the dummy gate trench T2 is buried by the buried layer 16, unlike in the first embodiment. Other configurations are the same as those of the first embodiment. In the second embodiment, since the inside of the dummy gate trench T2 is not buried by the dummy gate electrode GM2, a stress generated in the dummy gate trench T2 can also be reduced. In the case of the second embodiment, a height of the buried layer 16 is preferably the same as that in the first embodiment.

### Third Embodiment

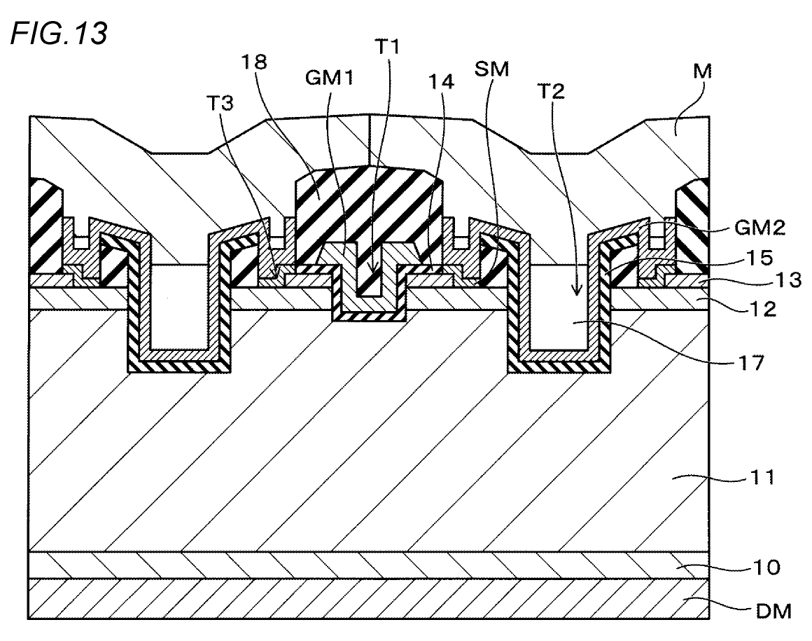

FIG. 13 is a cross-sectional view showing a configuration of a semiconductor device according to a third embodiment, which is a cross-sectional view perpendicular to a substrate main surface. As shown in FIG. 13, the semiconductor device according to the third embodiment has a structure in which the entire dummy gate trench T2 is formed as the void 17 without providing the buried layer 16, unlike in the first embodiment. Other configurations are the same as those of the first embodiment. In the third embodiment, since the entire inside of the dummy gate trench T2 is the void 17, a strain due to a difference in thermal expansion coefficient can be greatly absorbed. A height of the void 17 in the third embodiment is preferably the same as the height of the buried layer 16 in the first embodiment and the second embodiments. In the third embodiment, a width of the dummy gate trench T2 is preferably 0.5 μm to 1.5 μm. Within this range, the void 17 can be easily formed in the entire dummy gate trench T2.

### Other Modifications

Although those in the first embodiment to the third embodiment are each a MISFET, the present invention can be applied to any field effect transistor having a gate trench structure and a dummy gate trench structure. For example, the present invention can be applied to IGBT, HFET, or the like.

In addition, although GaN is used as the drift layer 11 and the p-type layer 12 the first embodiment to the third embodiment, any a nitride semiconductor may be used. However, GaN is preferred. In the case where the drift layer 11 and the p-type layer 12 are each a nitride semiconductor, piezoelectric charges are generated due to a stress, and a property fluctuation and property deterioration occur, so that the dummy trench structure in the present invention effectively functions. The substrate 10 and the n-type layer 13 may each be a semiconductor other than a nitride semiconductor.

In addition, in the first embodiment to the third embodiment, a structure in which the n-type and p-type are interchangeable may also be used.

### REFERENCE SIGNS LIST

10: substrate

11: drift layer

12: p-type layer

13: n-type layer

14: gate insulating film

15: dummy gate insulating film

16: buried layer

17: void

18: interlayer insulating film

GM1: gate electrode

GM2: dummy gate electrode

SM: source electrode

DM: drain electrode

M: wiring electrode

T1: gate trench

T2: dummy gate trench

T3: recess

What is claimed is:

1. A semiconductor device comprising:
a substrate comprising a first conductivity type semiconductor;
a first semiconductor layer being over the substrate and comprising a first conductivity type nitride semiconductor;
a second semiconductor layer being over the first semiconductor layer and comprising a second conductivity type nitride semiconductor;
a third semiconductor layer being over the second semiconductor layer and having a first conductivity type;
a gate trench penetrating the third semiconductor layer and the second semiconductor layer to reach the first semiconductor layer;
a gate insulating film provided in a film shape along a bottom surface and a side surface of the gate trench;
a gate electrode provided in a film shape along the bottom surface and the side surface of the gate trench via the gate insulating film;
a dummy gate trench provided apart from the gate trench, penetrating the third semiconductor layer and the second semiconductor layer to reach the first semiconductor layer, and being deeper than the gate trench;
a dummy gate insulating film provided in a film shape along a bottom surface and a side surface of the dummy gate trench;
a dummy gate electrode provided in a film shape along the bottom surface and the side surface of the dummy gate trench via the dummy gate insulating film; and
a buried layer comprising a material having a smaller thermal expansion coefficient than the dummy gate electrode, being over the dummy gate electrode, and burying an inside of the dummy gate trench.

2. The semiconductor device according to claim 1, wherein the buried layer has a void.

3. The semiconductor device according to claim 1, wherein the buried layer is provided to a position higher than the second semiconductor layer.

4. The semiconductor device according to claim 2, wherein the buried layer is provided to a position higher than the second semiconductor layer.

5. The semiconductor device according to claim 1, wherein the dummy gate trench has a width of 0.5 μm to 3 μm.

6. The semiconductor device according to claim 2, wherein the dummy gate trench has a width of 0.5 μm to 3 μm.

7. A semiconductor device comprising:
a substrate comprising a first conductivity type semiconductor;
a first semiconductor layer being over the substrate and comprising a first conductivity type nitride semiconductor;
a second semiconductor layer being over the first semiconductor layer and comprising a second conductivity type nitride semiconductor;
a third semiconductor layer being over the second semiconductor layer and having a first conductivity type;
a gate trench penetrating the third semiconductor layer and the second semiconductor layer to reach the first semiconductor layer;
a gate insulating film provided in a film shape along a bottom surface and a side surface of the gate trench;
a gate electrode provided in a film shape along the bottom surface and the side surface of the gate trench via the gate insulating film;
a dummy gate trench provided apart from the gate trench, and penetrating the third semiconductor layer and the second semiconductor layer to reach the first semiconductor layer;
a dummy gate insulating film provided in a film shape along a bottom surface and a side surface of the dummy gate trench; and
a dummy gate electrode provided in a film shape along the bottom surface and the side surface of the dummy gate trench via the dummy gate insulating film, wherein
a void is formed inside the dummy gate trench near the bottom surface without the dummy gate trench near the bottom surface being buried.

8. The semiconductor device according to claim 7, wherein the void is provided to a position higher than the second semiconductor layer.

9. The semiconductor device according to claim 7, wherein the dummy gate trench has a width of 0.5 μm to 1.5 μm.

10. The semiconductor device according to claim 8, wherein the dummy gate trench has a width of 0.5 μm to 1.5 μm.

11. The semiconductor device according to claim 1, further comprising:
a recess provided apart from the gate trench and penetrating the third semiconductor layer to reach the second semiconductor layer, wherein
the dummy gate trench is provided inside the recess in a plan view.

12. The semiconductor device according to claim 7, further comprising:
a recess provided apart from the gate trench and penetrating the third semiconductor layer to reach the second semiconductor layer, wherein
the dummy gate trench is provided inside the recess in a plan view.
